(19) United States
(12) Patent Application Publication
(10) Pub. No.: US 2013/0228204 A1
(43) Pub. Date: Sep. 5, 2013

(54) SEMICONDUCTOR ELEMENT FORMED OF THERMOELECTRIC MATERIAL FOR USE IN A THERMOELECTRIC MODULE AND THERMOELECTRIC MODULE HAVING SEMICONDUCTOR ELEMENTS

(71) Applicants: EMITEC GESELLSCHAFT FUER EMISSIONSTECHNOLOGIE MBH, Lohmar (DE); BAYERISCHE MOTOREN WERKE AKTIENGESELLSCHAFT, Muenchen (DE)

(72) Inventors: SIGRID LIMBECK, MUCH (DE); ROLF BRUECK, BERGISCH GLADBACH (DE); BORIS MAZAR, MUENCHEN (DE); ANDREAS EDER EDER, MUENCHEN (DE); MATTHIAS LINDE, MUENCHEN (DE)

(73) Assignees: BAYERISCHE MOTOREN WERKE AKTIENGESELLSCHAFT, MUENCHEN (DE); EMITEC GESELLSCHAFT FUER EMISSIONSTECHNOLOGIE MBH, LOHMAR (DE)

(21) Appl. No.: 13/867,615

(22) Filed: Apr. 22, 2013

Related U.S. Application Data
(63) Continuation of application No. PCT/EP2011/068089, filed on Oct. 17, 2011.

(30) Foreign Application Priority Data
Oct. 22, 2010 (DE) 10 2010 049 300.7

(51) Int. Cl. H01L 35/32

(52) U.S. Cl. CPC H01L 35/32
USPC 136/200

(57) ABSTRACT

A semiconductor element is formed of a thermoelectric material having at least one aperture, a first end face and an opposite second end face. A cross-sectional surface which is parallel to the first end face or to the second end face extends through the thermoelectric material and through the aperture and has an area which is at most 20% greater than the first front surface and is smaller than the second end face. A thermoelectric module having at least two semiconductor elements is also provided.

### CROSS-REFERENCE TO RELATED APPLICATION

This application is a continuation, under 35 U.S.C. §120, of copending International Application No. PCT/EP2011/068089, filed Oct. 17, 2011, which designated the United States; this application also claims the priority, under 35 U.S.C. §119, of German Patent Application No. DE 10 2010 049 300.7, filed Oct. 22, 2010; the prior applications are herewith incorporated by reference in their entirety.

### BACKGROUND OF THE INVENTION

### Field of the Invention

The present invention relates to a semiconductor element formed of thermoelectric material for use in a thermoelectric module. A thermoelectric module is used for the generation of electrical energy, e.g. from the exhaust gas of an internal combustion engine of a motor vehicle by using a generator. This means, in particular, a generator for the conversion of thermal energy of an exhaust gas into electrical energy, i.e. a so-called thermoelectric generator. The invention also relates to a thermoelectric module having at least two semiconductor elements.

The exhaust gas from an engine of a motor vehicle contains thermal energy, which can be converted by using a thermoelectric generator into electrical energy, e.g. for charging a battery or a different energy storage device or for directly delivering the required energy to electrical consumers. The motor vehicle is thereby operated with improved energy efficiency, and energy is more widely available for the operation of the motor vehicle.

Such a thermoelectric generator includes at least one thermoelectric module. Thermoelectric materials are of such a type that they can effectively convert thermal energy into electrical energy (Seebeck effect) and vice-versa (Peltier effect). Such thermoelectric modules preferably include a plurality of thermoelectric elements, which are positioned between a so-called hot side and a so-called cold side. Thermoelectric elements include at least two semiconductor elements (p-doped and n-doped), which are provided with electrically conducting bridges on their top side and underside alternately towards the hot side or towards the cold side. Ceramic plates or ceramic coatings and/or similar materials are used for the insulation of the metal bridges relative to a housing enclosing the thermoelectric module and are thus preferably disposed between the metal bridges and the housing. If a temperature gradient is provided on both sides of the semiconductor element, a voltage potential is formed between the ends of the semiconductor element. The charge carriers on the hotter side are increasingly excited in the conduction band by the higher temperature. Through the difference in concentration in the conduction band generated thereby, charge carriers diffuse to the colder side of the semiconductor element, resulting in the potential difference. In a thermoelectric module, in particular, numerous thermoelectric elements are electrically connected in series. In order to ensure that the generated potential difference of the serial semiconductor elements do not cancel each other out, alternating semiconductor elements with different majority charge carriers (n-doped and p-doped) are always brought into direct electrical contact. The circuit can be closed by using a connected load resistance and electrical power can thus be tapped.

Attempts have already been made to provide suitable thermoelectric generators for use in motor vehicles, in particular automobiles. Those were, however, mainly very expensive to manufacture and were distinguished by relatively low efficiency. Thus, series production has not yet been possible.

### SUMMARY OF THE INVENTION

It is accordingly an object of the invention to provide a semiconductor element formed of thermoelectric material for use in a thermoelectric module and a thermoelectric module having semiconductor elements, which overcome the hereinafore-mentioned disadvantages and at least partly solve the highlighted problems of the heretofore-known elements and modules of this general type. In particular, a semiconductor element is to be provided, which enables improved efficiency with respect to the conversion of provided thermal energy into electrical energy while simultaneously taking into account the quantity of cost-intensive semiconductor material applied.

With the foregoing and other objects in view there is provided, in accordance with the invention, a semiconductor element formed of thermoelectric material, comprising at least one aperture, a first end face and an oppositely disposed second end face. A cross-sectional surface, which is parallel to the first end face or to the second end face, extends through the thermoelectric material and through the aperture, and forms an area at most 20% greater than the first end face. At the same time, the cross-sectional surface has a smaller area than the second end face.

The semiconductor element is, in particular, an n-doped or p-doped semiconductor element and thus is suitable for the formation of a thermoelectric element, which can be used in thermoelectric modules for the generation of electrical energy from the thermal energy e.g. of an exhaust gas. The first end face and the oppositely disposed second end face are associated with a hot side or a cold side, so that heat can flow from the first end face to the second end face or vice-versa through the semiconductor material. As a result of this flow of heat, an electrical current is produced within the correspondingly electrically wired thermoelectric element, so that an electrical current flows through the thermoelectric element and can be tapped at contacts provided for that purpose.

The semiconductor element according to the invention now includes end faces of different sizes. Such semiconductor elements are e.g. used as annular semiconductor elements in tubular thermoelectric modules, wherein one end face is then formed by an outer circumferential surface and another end face is formed by an inner circumferential surface of the annular semiconductor element. In this case the outer circumferential surface is usually larger than the inner circumferential surface. The electrical current generation of a semiconductor element formed of thermoelectric material is approximately proportional to the cross-sectional area through which a flow of heat flows. For annular semiconductor elements there would thus be an excess of thermoelectric material in proximity to the outer circumferential surface, because the larger cross-sectional area is not necessary for the (limited) heat flow. The provision of the aperture(s) allows adaptation to the limited flow of heat, so that now practically in (almost) any cross section substantially the same thermoelectric material is effectively provided for the (limited) heat flow/generated electrical current. In other words, in this way the variation of the external shape with respect to the end faces towards the hot side and towards the cold side is compensated by a reduction of the internal thermoelectric material.

In order to save thermoelectric material that is not required as a result, it is also proposed to provide a semiconductor element with at least one aperture. In particular, the provision and/or shaping of the aperture(s) take/takes place in such a way that the increase in the cross section in the radial direction or in the direction of the height of the semiconductor element is substantially compensated. This particularly preferably applies at least over a proportion of at least 60% (or even at least 80%) of the height of the semiconductor element, which extends between the first end face and the second end face. Thus, e.g. at least 20% or even at least 40% of the thermoelectric material can be saved as compared to an equal-sized semiconductor element without recesses or apertures, without the effectiveness and/or functionality thereof being noticeably adversely affected. This leads to a significant cost saving, which is of particular importance in view of the currently expensive thermoelectric materials and the desire for mass production of such generators.

In accordance with another particularly advantageous feature of the semiconductor element of the invention, the cross-sectional area corresponds at least to the first end face. In other words, this means that the cross-sectional area in the thermoelectric material should not be less than the smaller of the two end faces, so that the semiconductor element has no so-called bottleneck within it. Such a “bottleneck” would restrict the flow of heat or the electrical current that can be generated by a corresponding, at least partial narrowing of the semiconductor element between the first end face and the second end face, so that the quantity of thermoelectric material used would not be used efficiently.

In accordance with a further particularly advantageous feature of the invention, the at least one aperture is at a distance from the first end face and the second end face. It is thereby achieved that the end face facing towards the hot side or the cold side is as large as possible, so that the thermoelectric material used per semiconductor element is used effectively. At the same time it is guaranteed that the semiconductor element is highly structurally stable (e.g. in the manner of a frame), because the aperture is within the semiconductor element and thus damage to the semiconductor element can be avoided, in particular during assembly of a thermoelectric module.

With the objects of the invention in view, there is also provided a semiconductor element having an annular segment shape and being formed of thermoelectric material, comprising an outer circumferential surface and an inner circumferential surface as well as a front side extending in the circumferential direction and an oppositely disposed rear side. The front side and rear side converge in a radial direction towards the outer circumferential surface, and a plurality of cross-sectional surfaces through the thermoelectric material parallel to the outer circumferential surface or to the inner circumferential surface each have an area that is at most 120% of the inner circumferential surface.

With a semiconductor element having an annular segment form, an implementation without recesses or apertures can also achieve the same effects while maintaining the same objective as has been illustrated above in relation to the first effect of the invention. The reduction of a cross-sectional surface between the inner circumferential surface and the outer circumferential surface is achieved in this case, in particular, through a continuous reduction/narrowing of the annular segment-shaped semiconductor element in the radial direction or over its height. The thickness of the annular segment-shaped semiconductor element is thus less in an axial direction at the outer circumferential surface than at the inner circumferential surface. Furthermore, the extent of the annular segment-shaped semiconductor element in the circumferential direction can be constructed so that the outer circumferential surface in the circumferential direction is narrower than the inner circumferential surface in the circumferential direction. Such an embodiment of the annular segment-shaped semiconductor element is likewise in accordance with the invention and leads to a plurality of cross-sectional surfaces through the thermoelectric material parallel to the outer circumferential surface or to the inner circumferential surface each having an area that is no more than 120% of the inner circumferential surface.

It is, of course, also possible that the convergence of the front side and the rear side is also provided in step form and/or by regions. In addition, at least one aperture in the above sense can also be additionally provided.

The reduction of the semiconductor element in the radial direction is preferably substantially adapted to the increase in the circumference or the peripheral cross-sectional area, so that also in this way, depending on the “short and thick” inner circumferential surface, a corresponding “longer and narrower” peripheral cross-sectional surface or finally a corresponding “longest and narrowest” outer circumferential surface is provided for the flow of heat or the flow of electrical current. For example, at least 20% or even at least 40% of the thermoelectric material can also thus be saved as compared to a semiconductor element of constant thickness without noticeably adversely affecting the effectiveness and/or functionality thereof.

In accordance with another special feature of the semiconductor element of the invention, the cross-sectional surface corresponds at least to the inner circumferential surface. It is thereby also achieved that no so-called bottleneck is produced between the outer circumferential surface and the inner circumferential surface, which would restrict the effectiveness of the semiconductor element in relation to the generation of an electrical current from the flow of heat passing therethrough.

With the objects of the invention in view, there is furthermore provided a semiconductor element formed of thermoelectric material, comprising a first end face and an oppositely disposed second end face as well as a front side and an oppositely disposed rear side and a first side and an oppositely disposed second side. The front side and the rear side converge in a direction from the first end face towards the second end face and the first side and the second side diverge in the same direction. A plurality of cross-sectional areas extend through the thermoelectric material parallel to the first end face or to the second end face, each have an area with a dimension, and the dimension only varies by at most 5%.

In particular, the first end face and the second end face have an identical size, but have a different geometric shape, so that the geometric shape of the first end face is connected to the geometric shape of the second end face by a non-parallel front side and rear side as well as a first side and a second side. In particular, likewise no so-called bottleneck is produced at the shape transition between the first end face and the second end face, which means that the magnitude of the area of the cross-sectional surface between the first end face and the second end face should likewise not change for end faces of identical size. In the event of end faces of different sizes, the corresponding cross-sectional surfaces between them, which are disposed one above the other, should continuously converge towards the size of the larger surface, from the smaller surface to the larger surface. The transition between the smaller surface and the larger surface takes place in particular linearly, so that there is a constant increase in the size of the cross-sectional surface for the same distance of the observed cross-sectional surfaces.

Of course, with the provision of a substantially constant cross section for the flow of heat/electrical current at least one aperture and/or a (partial) narrowing can be additionally provided.

With the objects of the invention in view, there is concomitantly provided a thermoelectric module, comprising at least two semiconductor elements according to the invention, which in particular are n-doped and p-doped and thus together form a thermoelectric element. For a specific embodiment of such a module, reference is made, in particular, to the embodiments in the introduction and the descriptions of the figures herein.

The invention is used, in particular, in a motor vehicle having a suitable thermoelectric module, which includes semiconductor elements according to the invention. The thermoelectric module is incorporated, in particular, in a thermoelectric generator, which preferably includes a plurality of thermoelectric modules. The thermoelectric generator feeds electrical energy extracted from the exhaust gas of an engine of the motor vehicle to a consumer or a battery of the motor vehicle.

Other features which are considered as characteristic for the invention are set forth in the appended claims, noting that the features listed individually in the claims can be combined with each other in any technologically purposeful manner and represent further embodiments of the invention.

Although the invention is illustrated and described herein as embodied in a semiconductor element formed of thermoelectric material for use in a thermoelectric module and a thermoelectric module having semiconductor elements, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, perspective view of a first structural variant of a semiconductor element;

FIG. 2 is a plan view of another first structural variant of a semiconductor element;

FIG. 3 is a cross-sectional view of a second structural variant of a semiconductor element;

FIG. 4 is a plan view of a semiconductor element according to FIG. 3;

FIG. 5 is a front-elevational view of a third structural variant of a semiconductor element;

FIG. 6 is a side-elevational view of the semiconductor element according to FIG. 5;

FIG. 7 is a first cross-sectional view of a surface of the semiconductor element of FIG. 5 and FIG. 6;

FIG. 8 is a second cross-sectional view of a surface of the semiconductor element of FIG. 5 and FIG. 6; and

FIG. 9 is a reduced, longitudinal-sectional view of a thermoelectric module according to the second structural variant having semiconductor elements according to the invention.

### DETAILED DESCRIPTION OF THE INVENTION

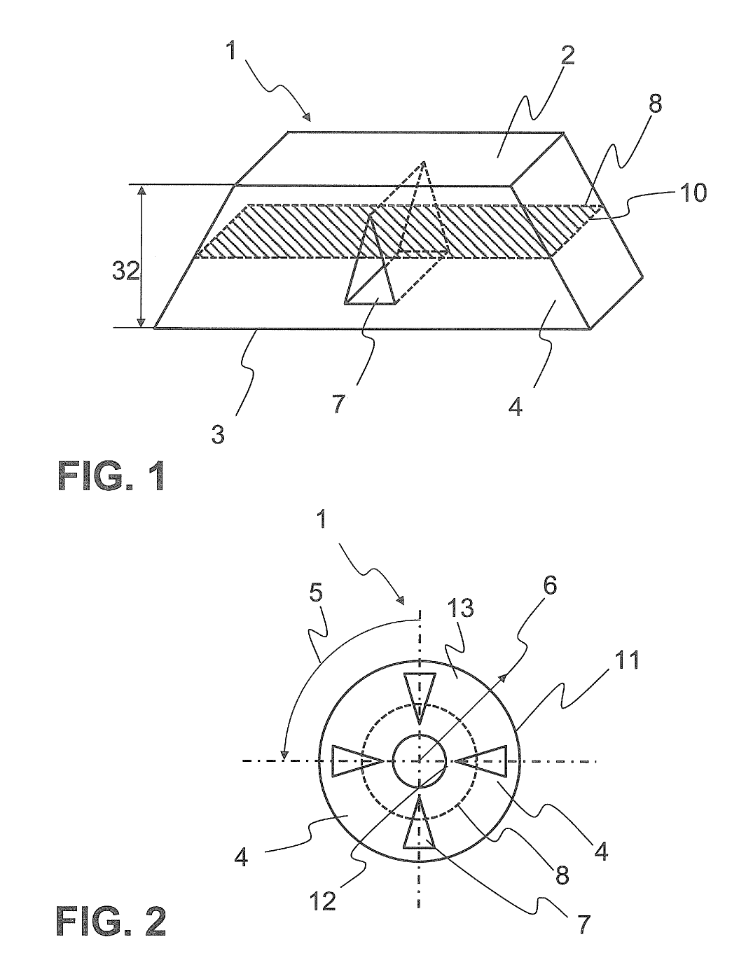

Referring now to the figures of the drawings in detail and first, particularly, to FIG. 1 thereof, there is seen a first structural variant of a semiconductor element 1 having a smaller first end face 2 and a larger second end face 3 formed of thermoelectric material 4. The first end face 2 is separated by a height 32 from the second end face 3. The semiconductor element 1 also includes an aperture 7, which extends within the thermoelectric material 4 through the semiconductor element 1. When installed in a thermoelectric module, the aperture or chamber 7 is filled, in particular, with air, vacuum, inert gas, ceramic or a mica material. A cross-sectional surface 8 is disposed parallel to the first end face 2 or to the second end face 3 and also intersects the aperture 7. The cross-sectional surface 8 has an area 10, which is no more than 20% larger than the first end face 2 and at the same time is smaller than the second end face 3. The cross-sectional surface 8 only contains the areas in which the thermoelectric material 4 is intersected. The cross-sectional surface 8 thus does not contain the areas in which the aperture 7 is intersected.

FIG. 2 shows another first structural variant of a semiconductor element 1. The semiconductor element 1 is implemented in annular form and accordingly includes an inner circumferential surface 12 and an outer circumferential surface 11, which bound or delimit the semiconductor element 1 internally and externally. Furthermore, the semiconductor element includes a front side 13 and a rear side that is not illustrated therein. Apertures 7 that can be seen on the front side 13 are disposed within the semiconductor element 1. In this case, a cross-sectional surface 8 is formed parallel to the first end face (inner circumferential surface 12) and to the second end face (outer circumferential surface 11). The cross-sectional surface 8 has an area that is no more than 20% larger than the inner circumferential surface 12 and at the same time has a smaller area than the outer circumferential surface 11. The thermoelectric material 4 of the semiconductor element 1 that is disposed in proximity to the outer circumferential surface 11 is correspondingly reduced by the apertures 7 that widen in a circumferential direction 5 with increasing distance in an outward radial direction 6. Thus, thermoelectric material 4 can be saved without reducing the efficiency of the semiconductor element 1 in operation, i.e. when installed in a thermoelectric module.

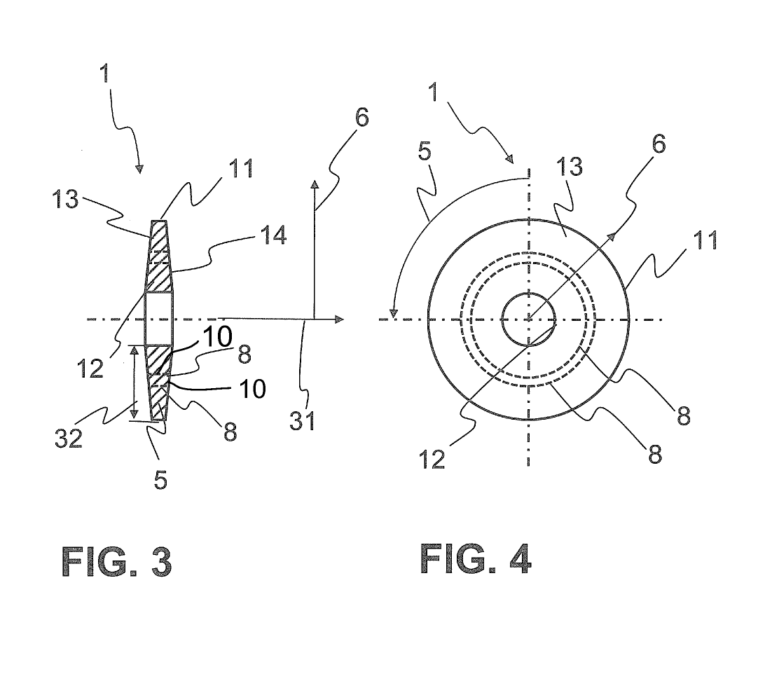

FIG. 3 shows a second structural variant of a semiconductor element 1 in cross section as seen from the side. The annular semiconductor element 1 includes an outer circumferential surface 11 and an inner circumferential surface 12, disposed at a distance from each other which defines a height 32 and is laterally bounded by a front side 13 and a rear side 14. A plurality of cross-sectional surfaces 8 are disposed within the semiconductor element 1, each having an area 10 parallel to the outer circumferential surface 11 or to the inner circumferential surface 12, which is no more than 120% of the inner circumferential surface 12. The thickness of the semiconductor element 1, which is defined by the distance of the front side 13 and rear side 14 from each other and which extends in an axial direction 31, decreases in a radial direction 6 starting from the inner circumferential surface 12 towards the outer circumferential surface 11, so that the mentioned condition for the semiconductor element 1 is fulfilled.

FIG. 4 shows the semiconductor element 1 according to FIG. 3 in a plan view, so that the front side 13 is visible therein in the plane of the image and the rear side 14 is concealed. The annular semiconductor element 1 is bounded externally by its outer circumferential surface 11 and internally by its inner circumferential surface 12 and includes cross-sectional surfaces 8 extending in the circumferential direction 5, disposed one on the other in the radial direction 6 and intersecting the semiconductor element 1 parallel to the outer circumferential surface 11 or in the circumferential surface 12.

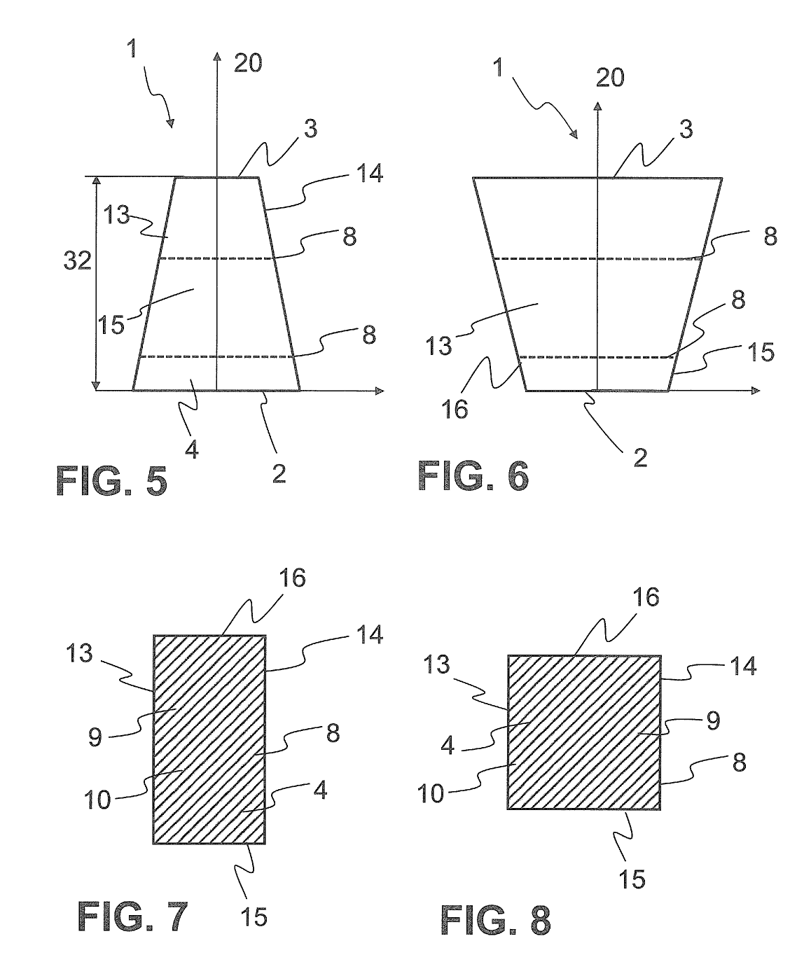

FIG. 5 shows a third structural variant of a semiconductor element 1. This variant includes a first end face 2 and a second end face 3, which are separated from each other by a height 32, a front side 13, a rear side 14, a first side 15 lying in the plane of the image as well as a second side 16 which is concealed in FIG. 5. The semiconductor element 1 having the thermoelectric material 4 in this case includes first and second cross-sectional surfaces 8, which are disposed one above the other and intersect the thermoelectric material 4 parallel to the first end face 2 or parallel to the second end face 3.

FIG. 6 shows the semiconductor element 1 of FIG. 5 in a view that is rotated through 90°, so that in this case the second side 16 is visible in addition to the first end face 2, the second end face 3, the front side 13 as well as the first side 15. In FIG. 6 the first side 15 and the second side 16 diverge from each other in a direction 20 starting from the first end face 2 towards the second end face 3, while in FIG. 5 the front side 13 and the rear side 14 converge towards each other in the direction 20 starting from the first end face 2 towards the second end face 3. The first and second cross-sectional surfaces 8 are also shown in FIG. 6.

FIG. 7 shows the first upper cross-sectional surface 8 shown in FIGS. 5 and 6, which extends through the thermoelectric material 4 between the front side 13, the rear side 14, the first side 15 and the second side 16. The cross-sectional surface 8 has an area 10 with a size 9 which deviates by no more than 5% as compared to the first end face 2 and the second end face 3.

Accordingly, FIG. 8 shows the second lower cross-sectional surface 8 of the semiconductor element 1 of FIGS. 5 and 6. The cross-sectional surface 8 is likewise bounded by the front side 13, the rear side 14, the first side or lateral surface 15 and second side or lateral surface 16. The cross-sectional surface 8 intersects the thermoelectric material and accordingly has an area 10 having a size 9, which likewise deviates from the first end face 2 and the second end face 3 by no more than 5%.

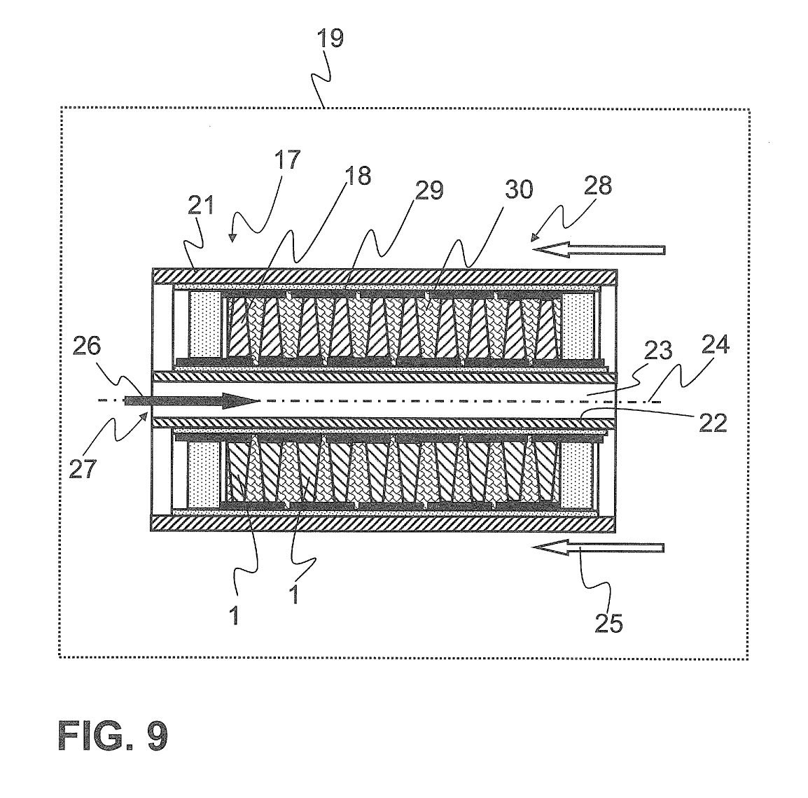

FIG. 9 shows a thermoelectric module 17 having a plurality of annular semiconductor elements 1 according to the second structural variant. The semiconductor elements are disposed in an annular manner about an inner tube 22 and within an outer tube 21. The inner tube 22 forms a duct 23, which carries a throughflow of a hot medium 26, thus carries a flow along a central axis 24 and therefore forms a hot side 27. A cold medium 25 flows over the outer tube 21 so that a cold side 28 is formed there. The semiconductor elements 1 thus extend between the cold side 28, which is formed by the outer tube 21, and the hot side 27, which is formed by the inner tube 22. The semiconductor elements 1 form pairs of thermoelectric elements 18 and are correspondingly disposed one after the other along the central axis 24 on the inner tube 22. Intervals between the semiconductor elements 1, which increase towards the outer tube, are filled with insulation material 30, which can include e.g. air, vacuum, inert gas, ceramic or even a mica material. The semiconductor elements 1 are alternately connected to each other on the side of the outer tube 21 and on the side of the inner tube 22 by metal bridges 29, so that an electric current is generated from the thermal energy of the hot medium 26 and can flow through the thermoelectric module 17. The thermoelectric module 17 is disposed within a motor vehicle 19, in particular within a thermoelectric generator.

1. A semiconductor element, comprising:
a thermoelectric material having at least one aperture formed therein;
first and second mutually oppositely disposed end faces; and
a cross-sectional surface disposed parallel to said first end face or parallel to said second end face and extending through said thermoelectric material and through said at least one aperture, said cross-sectional surface forming an area being at most 20% greater than said first end face and smaller than said second end face.

2. The semiconductor element according to claim 1, wherein said cross-sectional surface corresponds at least to said first end face.

3. The semiconductor element according to claim 1, wherein said at least one aperture is disposed at a distance from said first end face and said second end face.

4. A semiconductor element, comprising:
an annular segment shape defining a circumferential direction, a radial direction, an outer circumferential surface and an inner circumferential surface;
a front side and an oppositely disposed rear side extending in said circumferential direction and converging in said radial direction towards said outer circumferential surface;
a thermoelectric material disposed between said front and rear sides; and
a multiplicity of cross-sectional surfaces extending through said thermoelectric material and parallel to said outer circumferential surface or to said inner circumferential surface, each of said cross-sectional surfaces having an area being at most 120% of said inner circumferential surface.

5. The semiconductor element according to claim 4, wherein said cross-sectional surface corresponds at least to said inner circumferential surface.

6. A semiconductor element, comprising:
a first end face and an oppositely disposed second end face;
a front side and an oppositely disposed rear side;
a first side and an oppositely disposed second side;
a thermoelectric material disposed between said first and second end faces, between said front and rear sides and between said first and second sides;
said front side and said rear side converging in a direction from said first end face towards said second end face;
said first side and said second side diverging in said direction; and
a multiplicity of cross-sectional surfaces extending through said thermoelectric material parallel to said first end face or to said second end face, said cross-sectional surfaces each having an area with a size and said sizes varying by at most 5%.

7. A thermoelectric module, comprising:
at least two semiconductor elements according to claim 1 together forming a thermoelectric element.

8. A thermoelectric module, comprising:
at least two semiconductor elements according to claim 4 together forming a thermoelectric element.

9. A thermoelectric module, comprising:
at least two semiconductor elements according to claim 6 together forming a thermoelectric element.
